(19) United States
(12) Patent Application Publication
(10) Pub. No.: US 2013/0291939 A1
(43) Pub. Date: Nov. 7, 2013

(54) EMITTER FOR SILICON SOLAR CELLS AND METHOD

(71) Applicants: Martin Kaes, Berlin (DE); Gunnar Stiller, Sunnyvale, CA (US); Jean Patrice Rakotoniaina, Cupertino, CA (US); Fritz G. Kirscht, Berlin (DE); Olivier Laparra, San Jose, CA (US); Kamel Ounadjela, Belmont, CA (US)

(72) Inventors: Martin Kaes, Berlin (DE); Gunnar Stiller, Sunnyvale, CA (US); Jean Patrice Rakotoniaina, Cupertino, CA (US); Fritz G. Kirscht, Berlin (DE); Olivier Laparra, San Jose, CA (US); Kamel Ounadjela, Belmont, CA (US)

(21) Appl. No.: 13/888,691

(22) Filed: May 7, 2013

Related U.S. Application Data
(60) Provisional application No. 61/643,799, filed on May 7, 2012.
(60) Provisional application No. 61/651,921, filed on May 25, 2012.

(51) Int. Cl. H01L 31/0288; H01L 31/18

(52) U.S. Cl. CPC H01L 31/0288; H01L 31/18
USPC 136/256; 438/57

(57) ABSTRACT

The present invention relates to photovoltaic devices such as silicon solar cells. Devices shown exhibit improved low light performance and increased breakdown strength. Reasons for such improvements includes emitter concentration profiles leading to significantly reduced leakage currents.

### RELATED APPLICATIONS

This patent application claims the benefit of priority, under 35 U.S.C. §119(e), to U.S. Provisional Patent Application Ser. No. 61/643,799, filed on May 7, 2012, and to U.S. Provisional Patent Application Ser. No. 61/651,921, filed on May 25, 2012, which are incorporated herein by reference in their entirety.

### BACKGROUND

Solar cells can be a viable energy source by utilizing their ability to convert sunlight to electrical energy. Silicon is a semiconductor material and the raw incoming material used in the manufacture of solar cells.

### BRIEF DESCRIPTION OF THE DRAWINGS

In the drawings, like numerals can be used to describe similar elements throughout the several views. Like numerals having different letter suffixes can be used to represent different views of similar elements. The drawings illustrate generally, by way of example, but not by way of limitation, various embodiments discussed in the present document.

FIG. 1 shows performance ratio versus irradiance according to at least one embodiment of the invention.

FIG. 2 shows a schematic a diode model according to at least one embodiment of the invention.

FIG. 3 shows efficiency versus illumination according to at least one embodiment of the invention.

FIG. 4 shows phosphorous depth versus concentration according to at least one embodiment of the invention.

FIG. 5 shows a method of forming according to at least one embodiment of the invention.

FIG. 6 shows a block diagram of a photovoltaic device according to at least one embodiment of the invention.

FIG. 7 shows a graph of reverse current according to at least one embodiment of the invention.

### DETAILED DESCRIPTION

We have established an emitter design and process that results in simultaneous essential improvement of cell characteristics in two critical areas: low-level light performance and cell breakdown strength. The latter improvement is only briefly described here (compare FIG. 9).

The following detailed description relates to low-level light performance, and reference is made to the accompanying drawings. The drawings form a part of the description and are provided by way of illustration, but not of limitation. The drawing embodiments are described in sufficient detail to enable those skilled in the art to practice the present subject matter. Other embodiments may be utilized and electrical, structural, or material changes may be made without departing from the scope of the present patent document.

Reference will now be made in detail to certain examples of the disclosed subject matter, some of which are illustrated in the accompanying drawings. While the disclosed subject matter will largely be described in conjunction with the accompanying drawings, it should be understood that such descriptions are not intended to limit the disclosed subject matter to those drawings. On the contrary, the disclosed subject matter is intended to cover all alternatives, modifications, and equivalents, which can be included within the scope of the presently disclosed subject matter, as defined by the claims.

Silicon enables high conversion efficiencies of solar cells and thereby high power output of related modules. The emitter is a cell component which strongly impacts the total power gain as well the cell breakdown characteristics. The latter is critical facing the actual trend towards larger modules. Currently, there exist various emitter designs for cell optimization in regard to total power gain and good breakdown performance. Total power gain involves balancing cell efficiency versus irradiation strength for the full spectrum of sunlight. The latter includes so-called low-level light performance which basically describes the effective power output of cells and related modules under weak insulation.

Low light level performance is an important parameter that greatly influences total energy yield of a PV system. This is especially important in low annual insolation regions such as Northern Europe or North East United States for example. Low light level performance can vary significantly even within a particular PV technology. In this contribution results of low light performance of three modules are presented. The first module uses silicon solar cells, the second module uses standard monocrystalline Si cell and the third module uses standard EG Si cells. The modules were first tested at NREL's Outdoor Testing Facility. The low light level performance of those three modules indicated a markedly higher module output on the module with silicon cells. Since angle of incidence, temperature and spectral variations can significantly influence these data, these modules were also measured using a Spire indoor solar simulator. Measurements at 200, 400, 600, 800 and 1000 W/m² corroborated our outdoor tests and the superior performance of the silicon cell based modules. We observed that the shunt resistance of the module with silicon cells is higher than that in the other two modules. We found that the higher performance ratio on silicon cells is driven by less recombination in the space charge region at the pn-junction of the emitter and, consequently, reduced leakage currents (J₀₂) on silicon cells. The lower j₀₂ values is a result of an improved emitter process which we think is more immune to leakage increasing effects occurring potentially in conjunction with further cell processing such as silver thick film metallization. We found a good correlation between experimental and simulation results.

Therefore, as the light intensity decreases the light IV curve is moving towards lower part of the diode characteristics where Rₛₕᵤₙₜ and J₀₂ (which describes recombination in space charge region) dominate. In this low light regime a decrease of Rₛₕᵤₙₜ below a certain limit is drastically reducing the V_{oc} and FF. Cells with higher Rₛₕᵤₙₜ are less affected. Large scale systems output have also confirmed higher performance module output in low light conditions for modules using cells described in the present disclosure.

The industry is becoming critically sensitive to solar energy delivered in kilowatt hour than in kilowatt at illumination peak intensity. The reason is that when comparing systems or modules, it is more relevant to compare the energy delivered during an entire day than the energy delivered during the peak illumination which happens during very few hours on the same day. For that reason, low light level performance is an important parameter that greatly influences total energy yield of a PV system. This is especially important in low annual insolation regions such as Northern Europe or North East United States for example. Low light level performance can vary significantly even within a particular PV technology. In this contribution results of low light performance of three modules are presented. The first module uses silicon solar cells described in the present disclosure, the second module uses standard monocrystalline Si cell and the third module uses standard EG Si cells. The modules were first tested at NREL's Outdoor Testing Facility. The low light level performance of those three modules indicated a markedly higher module output on the module with silicon solar cells described in the present disclosure. Since angle of incidence, temperature and spectral variations can significantly influence these data, these modules were also measured using a Spire indoor solar simulator. Measurements at 200, 400, 600, 800 and 1000 W/m² corroborated our outdoor tests and the superior performance of the UMG-based modules. We observed that the shunt resistance of the module with silicon solar cells described in the present disclosure is higher than that in the other two. As the light intensity decreases the light IV curve is moving towards lower part of the diode characteristics where Rₛₕᵤₙₜ and J₀₂ (which describes recombination in space charge region) dominate. In this low light regime a decrease of Rₛₕᵤₙₜ below a certain limit is drastically reducing the Voc and FF. Cells with higher Rₛₕᵤₙₜ are less affected. Large scale systems output have also confirmed higher performance module output in low light conditions for modules using silicon solar cells described in the present disclosure.

### Explanatory Pages

Module efficiency is measured at 1 sun according to IEC 61215 or UL1703. In real conditions, however, illumination can be less than 1 sun, a so called low level intensity. Bunea et al. investigated low light level performance of monocrystalline silicon solar cells. They found that a solar cell with higher shunt value can have a better low-light level illumination correlation. Glunz et al. investigated low-illumination on high efficiency PERC cells. They explained the loss on low level performance based on edge shunt or the space charge region described by J₀₂ in the two diode-model. In this paper we present a comparison of low light level performance of three modules. One of the modules is made of Calisolar silicon cells. Among other products, Calisolar manufactures solar cells based on 100% compensated solar silicon.

### Experimental Results

Three different modules have been compared. One module with silicon solar cells described in the present disclosure, the second module using electronic grade (EG) cells and the third module using monocrystalline cells. Two modules use the standard 60 cells/module configuration, one module a 72 cells/module configuration. All modules were mounted at the same locations at NREL Outdoor Test Facility (OTF). This allows an identical weather conditions for all of the three modules (illumination, wind speed, temperature, etc . . . ). Further, these modules have the same incidence angle and solar insolation at any given time.

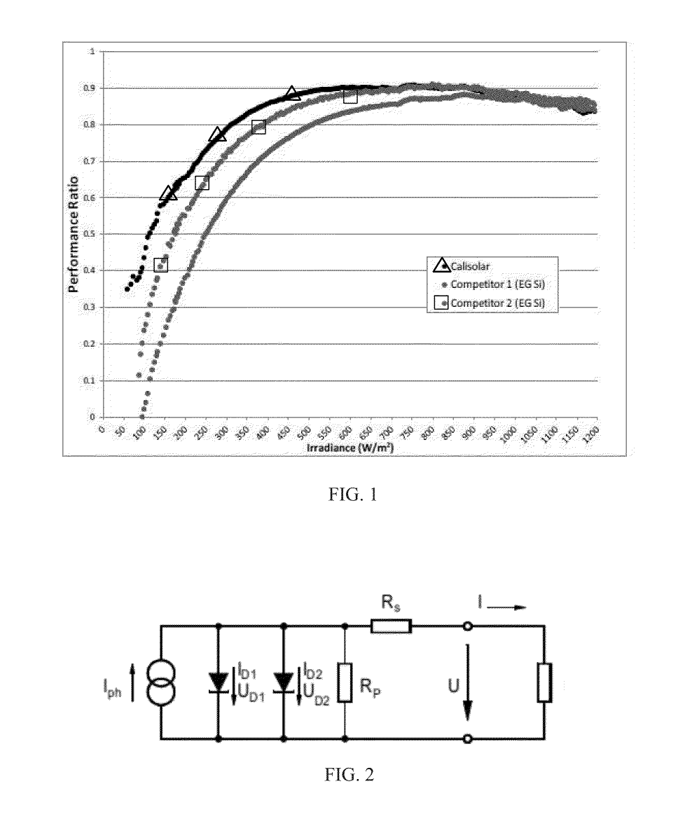

FIG. 1 shows Performance Ratio PR as a function of the light illuminations for all three modules. FIG. 1 shows the results of the Performance Ratio as function of the light intensity. Performance Ratio (PR) is the ratio of the energy yield and incident illumination. PR allows a good comparison eliminating e.g. module power output as well as module design.

As shown in FIG. 1, as light intensity decreases low level performance decreases. However the PR of the module made of UMG cells remained high compared to the two competitor modules. At 0.2 sun the PR of module made from silicon solar cells described in the present disclosure is 0.65.

Table 1 shows the shunt Resistance of the three modules. To better understand the effect of shunt resistance on low-light level performance we performed a simulation using a two diode model described by equation (1) and presented in FIG. 2). FIG. 2 shows a schematic of the two diode model with shunt and serial resistance.

TABLE 1

| Manufacturer | Shunt resistance [Ohm/cell] |
|---|---|
| Calisolar | 1745 |
| Manufacturer 1 | 25.3 |
| Manufacturer 2 | 63.2 |

$$I = {I}_{PH} - {I}_{01} ( {e}^{( U + I \times {R}_{S / kT} )} - 1 ) - {I}_{02} ( {e}^{( U + I \times {R}_{S / 2 kT} )} - 1 ) {-}^{( U + I \times {R}_{s} )} / {R}_{p} \qquad Equation 1$$

Equation 1 describes a two diode model equation describing a good approximation to a solar cell: I_{PH} being the photon current, I₀₁ and I₀₂ being the saturation diode currents, Rₛ being the serial resistance and Rₚ the shunt resistance, k being the Boltzmann factor and T the temperature.

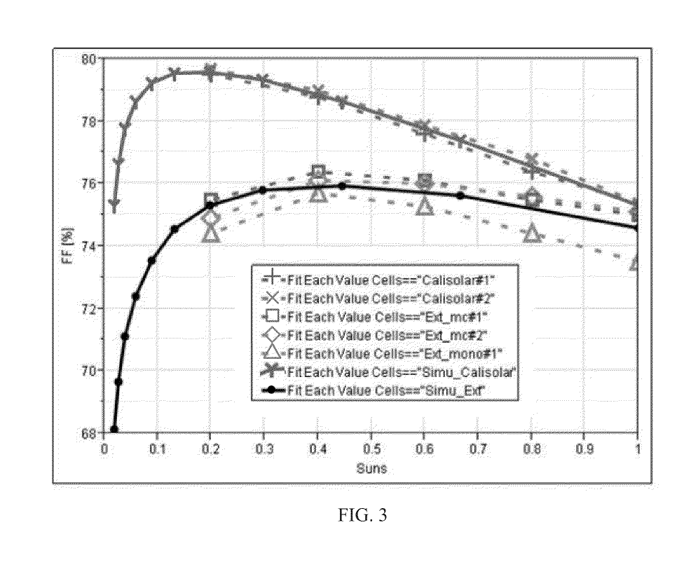

FIG. 3 shows a simulation results of fill factor vs. light illumination and comparison to experimental data of the 3 module types. Simulation used the parameters in Table 2. Red curve shows module with silicon solar cells described in the present disclosure.

TABLE 2

| | Simu_Calisolar | Simu_Ext |
|---|---|---|
| RShunt [kOhmcm²] | 30 | 30 |
| RSer [Ohmcm²] | 1.55 | 1.15 |
| J₀₁ [10⁻¹² A/cm²] | 0.75 | 0.75 |
| J₀₂ [10⁻⁸ A/cm²] | 0.6 | 4 |
| n1 | 1 | 1 |
| n2 | 2 | 2 |

Table 2 shows parameters used for the simulation of two modules (Calisolar (silicon solar cells described in the present disclosure) and modules from the external suppliers) where the results are presented in FIG. 3. Based on the two diode model described in equation (1), as the light intensity decreases, the light IV curve is moving forward to the part where J₀₂ and Rₛₕᵤₙₜ dominate the fill factor. The simulation results in FIG. 3 show clearly the red curve lower leakage diode current J₀₂ indicating less drop in efficiency due to significant fill factor increases as the light level decreases.

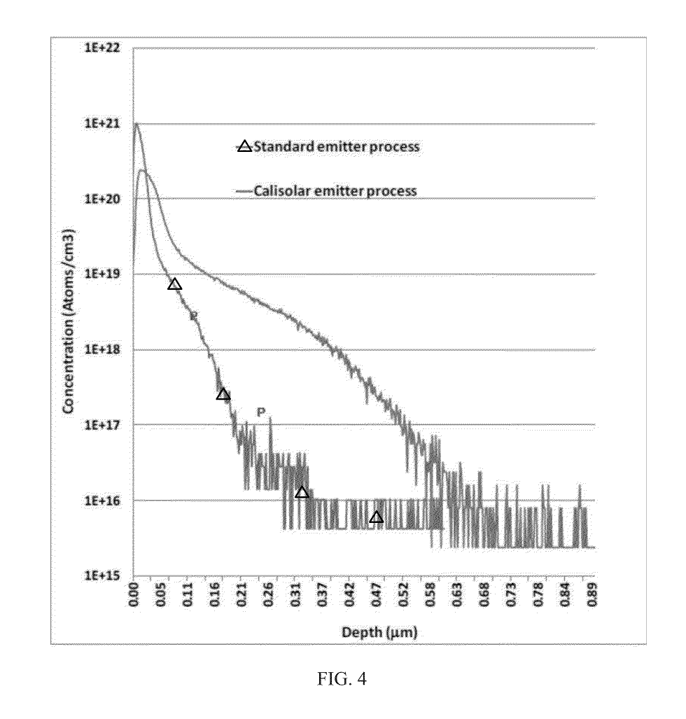

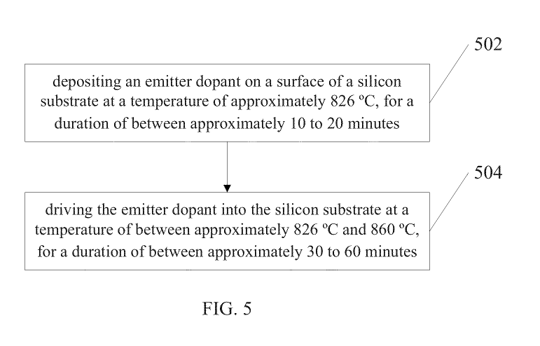

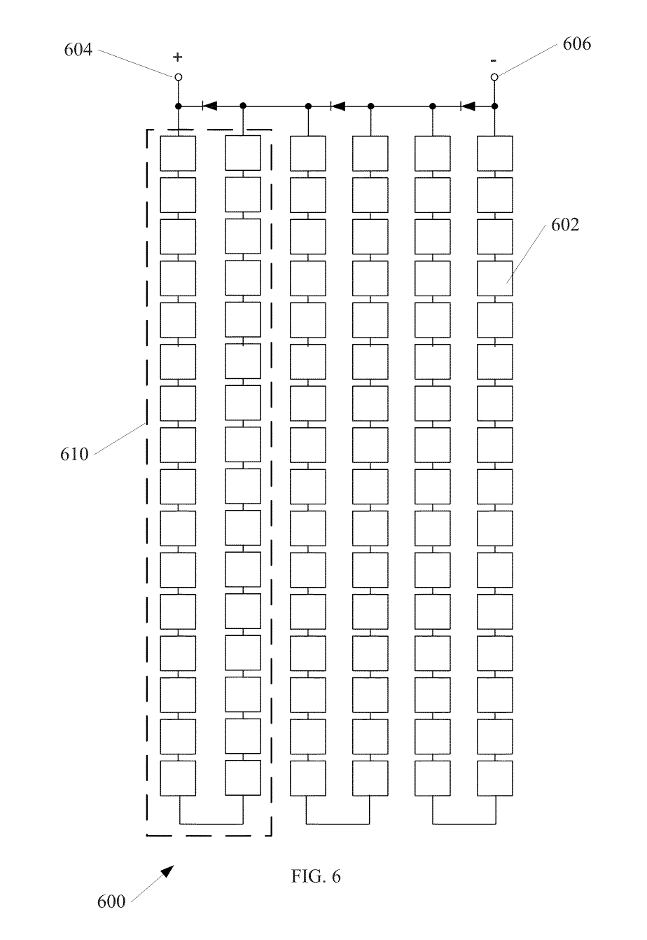

In FIG. 4, SIMS measurement is performed on cells which were fabricated using the improved emitter process shows deeper profile and lower dead layer which have a significant impact in both the shunt and series resistances and the diode dark saturation current J₀₂. FIG. 6 shows phosphorus measured by SIMS. Comparison of an improved and standard emitter. Improved process shows thinner dead layer and a deeper junction profile. In one example, a junction depth is defined as a depth at which an emitter dopant (e.g. phosphorous) concentration becomes lower than approximately 1×10¹⁶ atoms/cm³.

The emitter profile of FIG. 4 shows a peak surface concentration of approximately 3×10²⁰ atoms/cm³, in contrast to the prior emitter peak surface concentration of approximately 1×10²¹ atoms/cm³. In one example, emitter profile features such as an emitter depth within a range of approximately 0.35-0.70 μm provides improved photovoltaic devices with improved low light performance as discussed above, and an improved junction breakdown voltage. In one example, a junction breakdown voltage is improved to greater than approximately 14.2 volts using configurations described in the present disclosure.

As mentioned earlier J₀₂ is an important parameter on the low level light performance. J₀₂ describes the generation and recombination in space charge region. It has been found that the silver contact formation by printing a silver thick film metallization paste with subsequent drying and firing is well known to increase J₀₂. The effect of J₀₂ related to the improved emitter on low level light needs more extended analysis. It has been found that the very thin emitter of typically several hundreds of nanometer is harmed by the glass frit etching and subsequently by the growing of inverted silver pyramids into the silicon. The size of the silver pyramids can be several hundreds of nanometer and therefore has about the same dimension than the emitter and the tips of the silver pyramids can even reach the base. Firing at higher temperatures can lead to a more aggressive glass etching and larger silver pyramids, thus usually a slight decrease in V_{oc} and fill factor is observed with increasing firing temperatures. Similar effects can be observed with plated or evaporated contacts like Ni or Ti during the sintering step: Longer and hotter sintering leads to Voc and fill factor losses likely due to heavy silicide formation. Thus the deep emitter profile described in the present disclosure, not only is expected to be beneficial for common thick film metallization but as well for next generation seed & plate metallization technologies.

FIG. 5 shows a flow diagram of an example method of forming an emitter junction according to an embodiment of the invention. In operation 502, an emitter dopant is deposited on a surface of a silicon substrate at a temperature of approximately 826° C., for a duration of between approximately 10 to 20 minutes. In one example, the emitter dopant includes phosphorous. In one example, POCl₃ is used as an emitter dopant source. In one example, the duration is approximately 15 minutes. In one example the emitter dopant source is deposited under pressure. In one example, the pressure of the emitter dopant source during deposition is approximately 200 mbar or lower.

In operation 504, the emitter dopant is driven into the silicon substrate at a temperature of between approximately 826° C. and 860° C., for a duration of between approximately 30 to 60 minutes. In one example, the temperature is ramped up from approximately 826° C. during deposition to approximately 860° C. during the drive in operation 704. In one example, the duration of operation 704 is approximately 51 minutes.

In one example, and oxidizing atmosphere is introduced to the emitter surface during the drive in operation 504. Examples of oxidizing atmospheres include, but are not limited to, pure O₂, O₂ diluted with N₂ or O₂ diluted with water vapor. In one example the emitter dopant drive in operation 504 is performed under pressure. In one example, the pressure during operation 504 is approximately 500 mbar or higher.

In one example the silicon substrate with the emitter dopant is cooled before removal from deposition and drive in equipment. In one example the silicon substrate with the emitter dopant is cooled to a temperature of between approximately 700° C. and 800° C. at a rate of between approximately 0.5° C./minute and 4.0° C./minute. In one example, the silicon substrate with the emitter dopant is cooled to a temperature of approximately 720° C. at a rate of approximately 2.0° C./minute.

FIG. 6 shows a photovoltaic device 600 according to an embodiment of the invention. The device 600 includes multiple cells 602, where each cell is a device similar to device 200 from FIG. 2. In one example, the device 600 includes 72 individual cells 602 coupled together to form the composite device 600 with positive 604 and negative 606 terminals.

The example of FIG. 6 is configured with three strings 610 of twenty four cells 602. In operation, if a single cell 602 of one of the strings 610 is in the shade, the shaded cell 602 is in a reverse bias condition within the string 610. In such an example, a reverse bias voltage from the other 23 cells may be 0.62 volts×23 cells=14.2 volts. In this example, a suitable breakdown voltage to prevent failure of the device 600 is greater than 14.2 volts.

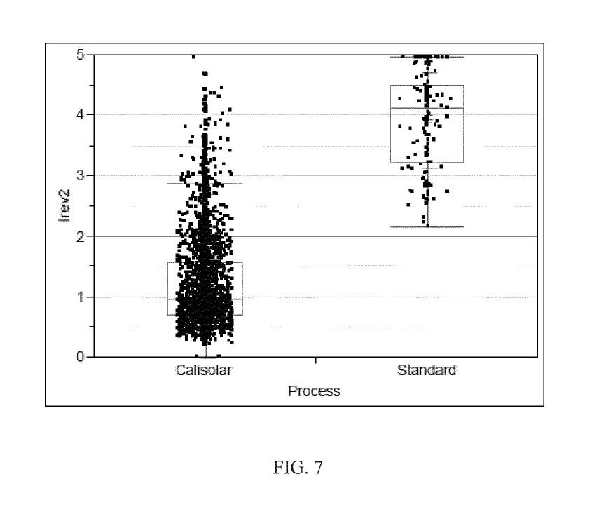

FIG. 7 shows the distribution of reverse current at −14.5 Volts for at least one embodiment of the invention versus conventional processing.

Using methods and devices including emitter configurations described in examples above, a breakdown voltage of each individual cell 802 is increased above 14.2 volts, and the device 800 is able to use 24 cells in each string without risk of an individual cell 802 failing due to an extreme reverse bias condition as described above. One of ordinary skill in the art, having the benefit of the present disclosure will recognize that other numbers of cells and strings are within the scope of the invention, and that an acceptable breakdown voltage may change depending on other variables such as the operating current, etc.

### Conclusions

We compared the low light performance of a module made with 100% Calisolar UMG cells (silicon solar cells described in the present disclosure) and two other modules. We have found that the performance ratio of the module with silicon solar cells described in the present disclosure is higher. This higher PR is driven two major components, the first one is the lower J₀₂ or less recombination in the space charge region on the silicon solar cells described in the present disclosure. The second effect i the higher shunt resistance on the icon solar cells described in the present disclosure. Higher shunt resistance and lower J₀₂ values are both results of an improved emitter process as described in the present disclosure. We found a good correlation between experimental and simulation results. This finding may explain the higher energy yield of modules using silicon solar cells described in the present disclosure.

What is claimed is:

1. A photovoltaic cell, comprising:
a silicon substrate;
a conductive back plate, coupled to a first side of the silicon substrate;
an emitter coupled to a second side of the silicon substrate, opposite the first side, the emitter having an emitter depth;
wherein the emitter depth is greater than approximately 0.35 μm.

2. The photovoltaic cell of claim 1, wherein the emitter depth is within a range of approximately 0.35-0.70 μm.

3. The photovoltaic cell of claim 1, wherein the emitter depth is within a range of approximately 0.40-0.60 μm.

4. The photovoltaic cell of claim 1, wherein an emitter dopant element includes phosphorous.

5. The photovoltaic cell of claim 4, wherein an emitter dopant concentration is greater than approximately 1×10¹⁸ atoms /cm³ at a depth of 0.30 μm.

6. The photovoltaic cell of claim 4, wherein an emitter dopant concentration is greater than approximately 1×10¹⁷ atoms /cm³ at a depth of 0.45 μm.

7. A method of forming a photovoltaic cell, comprising:
depositing an emitter dopant on a surface of a silicon substrate at a temperature of approximately 826° C., for a duration of between approximately 10 to 20 minutes; and
driving the emitter dopant into the silicon substrate at a temperature of between approximately 826° C. and 860° C., for a duration of between approximately 30 to 60 minutes.

8. The method of claim 7, further including cooling the photovoltaic cell to a temperature of between approximately 700° C. and 800° C. at a rate of between approximately 0.5° C./minute and 4.0° C./minute.

9. The method of claim 7, further including cooling the photovoltaic cell to a temperature of approximately 720° C. at a rate of approximately 2.0° C./minute.

10. The method of claim 7, further including driving the emitter dopant into the silicon substrate in an oxidizing atmosphere.

11. The method of claim 7, further including depositing an emitter dopant on a surface of a silicon substrate at a first pressure greater than atmospheric pressure.

12. The method of claim 11, further including driving the emitter dopant into the silicon substrate at a second pressure greater than atmospheric pressure.

13. The method of claim 12, wherein the second pressure is greater than the first pressure.
